(19) United States
(12) Patent Application Publication
(10) Pub. No.: US 2014/0250647 A1
(43) Pub. Date: Sep. 11, 2014

(54) METHOD FOR FABRICATING PIEZOELECTRIC DEVICE

(71) Applicant: NIHON DEMPA KOGYO CO., LTD., TOKYO (JP)

(72) Inventors: TAKESHI UCHIDA, SAITAMA (JP); TAKAHIRO YOSHIMURA, SAITAMA (JP)

(73) Assignee: NIHON DEMPA KOGYO CO., LTD., TOKYO (JP)

(21) Appl. No.: 14/190,104

(22) Filed: Feb. 26, 2014

(30) Foreign Application Priority Data
Mar. 5, 2013 (JP) 2013-043097

(51) Int. Cl. H01L 41/293

(52) U.S. Cl. CPC H01L 41/293
USPC 29/25.35

(57) ABSTRACT

A method for fabricating a piezoelectric device that includes a piezoelectric resonator to be mounted on a solder applied over a surface of a substrate. The piezoelectric resonator includes a metal case and at least a pair of lead terminals extracted from the metal case. The lead terminal includes a first part, a second part, and a third part. The method includes: applying solder cream at a case region and a lead region of a surface of the substrate, the case region corresponding to the metal case, the lead region corresponding to the third part; placing a block solder with a smaller area than an area of the case region at the case region; arranging the metal case of the piezoelectric resonator to the case region, arranging the third part to the lead region; and heating the substrate and the piezoelectric resonator in a reflow furnace.

### CROSS REFERENCE TO RELATED APPLICATIONS

This application claims the priority benefit of Japan application serial no. 2013-043097, filed on Mar. 5, 2013. The entirety of the above-mentioned patent application is hereby incorporated by reference herein and made a part of this specification.

### TECHNICAL FIELD

This disclosure relates to a method for fabricating a piezoelectric device where a piezoelectric resonator is mounted on a printed circuit board.

### DESCRIPTION OF THE RELATED ART

A piezoelectric device where a piezoelectric resonator with predetermined vibration frequency is bonded on a printed circuit board via solder is known. Such piezoelectric device includes an oven-controlled piezoelectric oscillator (an oven controlled crystal oscillator (OCXO)), for example. The oven-controlled piezoelectric oscillator (OCXO) is employed as a reference signal source for, for example, a GPS frequency generator and a base station for mobile terminal. Even under poor environment such as ambient temperature changes and high-temperature and humidity, the oven piezoelectric oscillator ensures stable oscillation output. For example, Japanese Unexamined Patent Application Publication No. 2008-306480 (hereinafter referred to as Patent Literature 1) discloses a piezoelectric oscillator with an oven where lead terminals of a piezoelectric resonator is electrically connected to a substrate. A pair of lead terminals of the piezoelectric resonator are fabricated and bonded on the printed circuit board with solder.

However, the lead terminals of the piezoelectric resonator disclosed in Patent Literature 1 causes the following problem. Due to a difference in length of each lead terminal or similar cause, one lead terminal insufficiently contacts the substrate.

A need thus exists for a method for fabricating a piezoelectric device which is not susceptible to the drawback mentioned above.

### SUMMARY

A method for fabricating a piezoelectric device according to a first aspect is configured as follows. The piezoelectric device includes a piezoelectric resonator to be mounted on a solder applied over a surface of a substrate. The piezoelectric resonator includes a metal case and at least a pair of lead terminals extracted from the metal case. The metal case houses a piezoelectric piece. The lead terminal includes a first part, a second part, and a third part. The first part is extracted parallel to a longitudinal direction of the metal case. The second part is then perpendicularly bent to the longitudinal direction. The third part is again bent to the longitudinal direction. The method includes: an applying process for applying solder cream at a case region and a lead region of a surface of the substrate, the case region is corresponding to the metal case, the lead region is corresponding to the third part; a placing process for placing a block solder at the case region, the block solder has a smaller area than an area of the case region; an arranging process for arranging the metal case of the piezoelectric resonator to the case region, and arranging the third part to the lead region; and a heating process for heating the substrate and the piezoelectric resonator in a reflow furnace.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a schematic cross-sectional view of a piezoelectric device 100.

FIG. 2 is a schematic exploded perspective view of a piezoelectric resonator 110 and a printed circuit board 120.

FIG. 3 is a flowchart illustrating a method for mounting the piezoelectric resonator 110 on the printed circuit board 120.

FIG. 4A is a side view of a piezoelectric resonator 210.

FIG. 4B is a front view of the piezoelectric resonator 210.

FIG. 5A is a side view of the printed circuit board 120 on which solder cream 161 is applied.

FIG. 5B is a side view of the printed circuit board 120 where a block solder 162 is placed.

FIG. 5C is a perspective view of the printed circuit board 120 where the block solder 162 is placed.

FIG. 6A is a side view of the printed circuit board 120 and the piezoelectric resonator 210.

FIG. 6B is a plan view of the printed circuit board 120 and the piezoelectric resonator 210.

FIG. 6C is a front view of the printed circuit board 120 and the piezoelectric resonator 210.

FIG. 7A is a side view of the printed circuit board 120 and the piezoelectric resonator 210 bonded to one another.

FIG. 7B is an enlarged figure of the lead terminal 212 bonded on the printed circuit board 120.

FIG. 8A is a side view of the printed circuit board 120 and the piezoelectric resonator 210 bonded to one another using a conventional method.

FIG. 8B is a plan view of the printed circuit board 120 and the piezoelectric resonator 210 bonded to one another using a conventional method.

### DETAILED DESCRIPTION

Various representative embodiments of this disclosure are described in detail below based on the drawings. It will be understood that the scope of the disclosure is not limited to the described embodiments, unless otherwise stated.

### Configuration of Piezoelectric Device 100

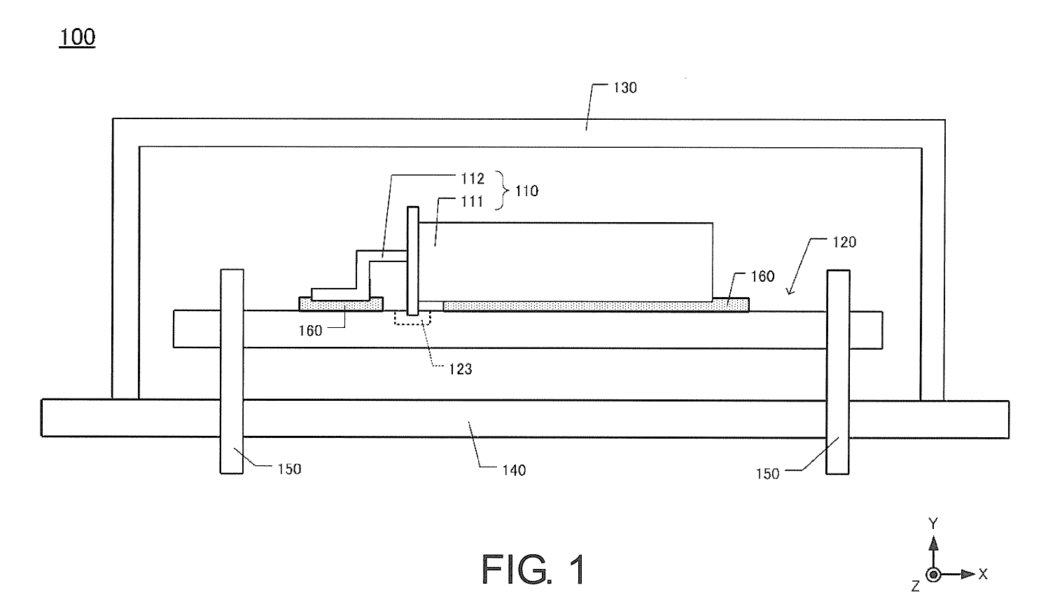

FIG. 1 is a schematic cross-sectional view of the piezoelectric device 100. The piezoelectric device 100 mainly includes a piezoelectric resonator 110, a printed circuit board 120, a base plate 140, and a cover 130. The piezoelectric resonator 110 is placed on the printed circuit board 120. The printed circuit board 120 is placed on the base plate 140. The cover 130 covers the piezoelectric resonator 110 and the printed circuit board 120. In the following description, the longitudinal direction of the piezoelectric resonator 110 on the printed circuit board 120 denotes the X-axis direction, the short side direction of the piezoelectric resonator 110 on the printed circuit board 120 and a direction perpendicular to the X-axis direction denotes the Z-axis direction, the direction perpendicular to the X-axis direction and the Z-axis direction and the vertical direction of the printed circuit board 120 denotes the Y-axis direction.

The piezoelectric resonator 110 includes a metal case 111 and a pair of lead terminals 112 extracted from the metal case 111. In the metal case 111, a piezoelectric piece (not illustrated) is placed. The piezoelectric piece includes an excitation electrode and vibrates at a predetermined vibration frequency. The excitation electrode is electrically connected to the lead terminal 112. The piezoelectric piece is formed of a single crystal material represented by crystal (SiO₂), Lithium tantalate (LiTaO₃), and Lithium Niobate (LiNbO₃). The metal case 111 and each lead terminal 112 of the piezoelectric resonator 110 are bonded on the printed circuit board 120 with a solder 160, respectively. The printed circuit board 120 is placed on the base plate 140 with a metal lead terminal 150. The metal lead terminal 150 is extracted to the −Y-axis side of the base plate 140. Furthermore, the piezoelectric resonator 110 and the printed circuit board 120 are covered with the cover 130.

The piezoelectric device 100 is, for example, an oven-controlled piezoelectric oscillator (an oven controlled crystal oscillator (OCXO)). In this case, the printed circuit board 120 includes an oscillation device, a heating element, a temperature sensor, a temperature control circuit (all of them are not illustrated), and similar member. The oscillation device oscillates the piezoelectric piece. The heating element serves as a heat source to maintain the temperature of the piezoelectric resonator 110. The temperature sensor measures the temperature of the piezoelectric resonator 110. The temperature control circuit controls the heating element and the temperature sensor. These electronic components maintain the piezoelectric resonator 110 at a predetermined temperature.

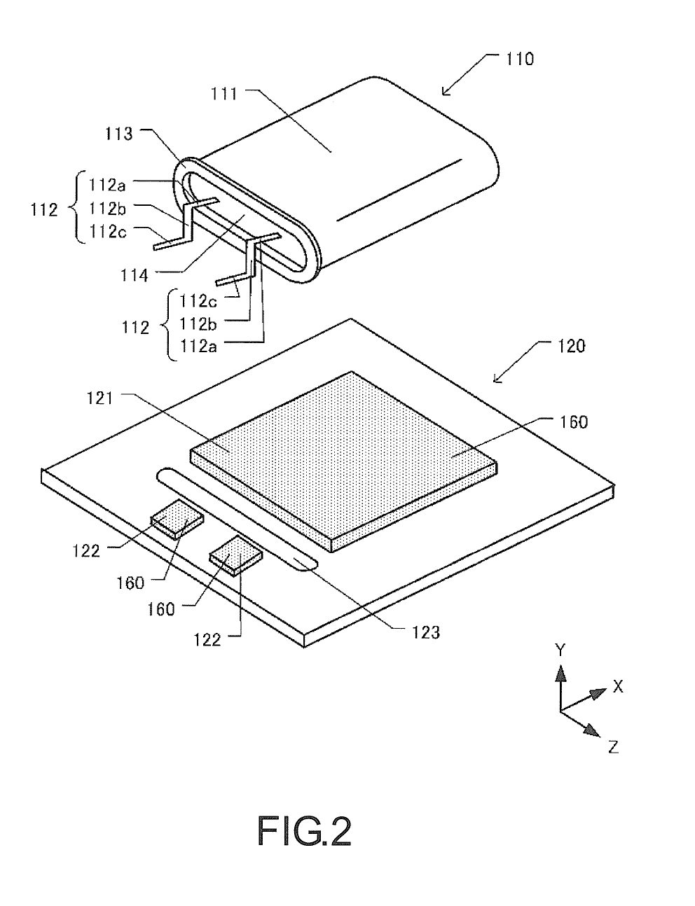

FIG. 2 is a schematic exploded perspective view of the piezoelectric resonator 110 and the printed circuit board 120. The piezoelectric resonator 110 forms a flange 113 by bonding of the metal case 111 with a surface 114 on which the lead terminals 112 are extracted. The pair of lead terminals 112 include first parts 112a, second parts 112b, and third parts 112c. The first part 112a is extracted from the surface 114 to the −X-axis direction. The second part 112b extends from an end of the −X-axis side of the first part 112a to the −Y-axis direction. The third part 112c extends from an end of −Y-axis side of the second part 112b to the −X-axis direction. These first part 112a, second part 112b, and third part 112c are formed by bending, for example, one lead terminal.

The printed circuit board 120 includes a case region 121 and a pair of lead regions 122. The metal case 111 of the piezoelectric resonator 110 is placed on the case region 121. The pair of lead terminals 112 are bonded to the pair of lead regions 122, respectively. Between the case region 121 and the lead regions 122, a hollow 123 is formed. The flange 113 of the piezoelectric resonator 110 fits inside of the hollow 123. The piezoelectric resonator 110 is placed on the printed circuit board 120 via the solders 160 formed on the case region 121 and the lead regions 122. In the piezoelectric device 100, when the surface of the −Y-axis side of the metal case 111 and the third part 112c of each lead terminal 112 are formed on the same plane, the piezoelectric resonator 110 is stably placed on the printed circuit board 120.

### Method for Mounting Piezoelectric Resonator

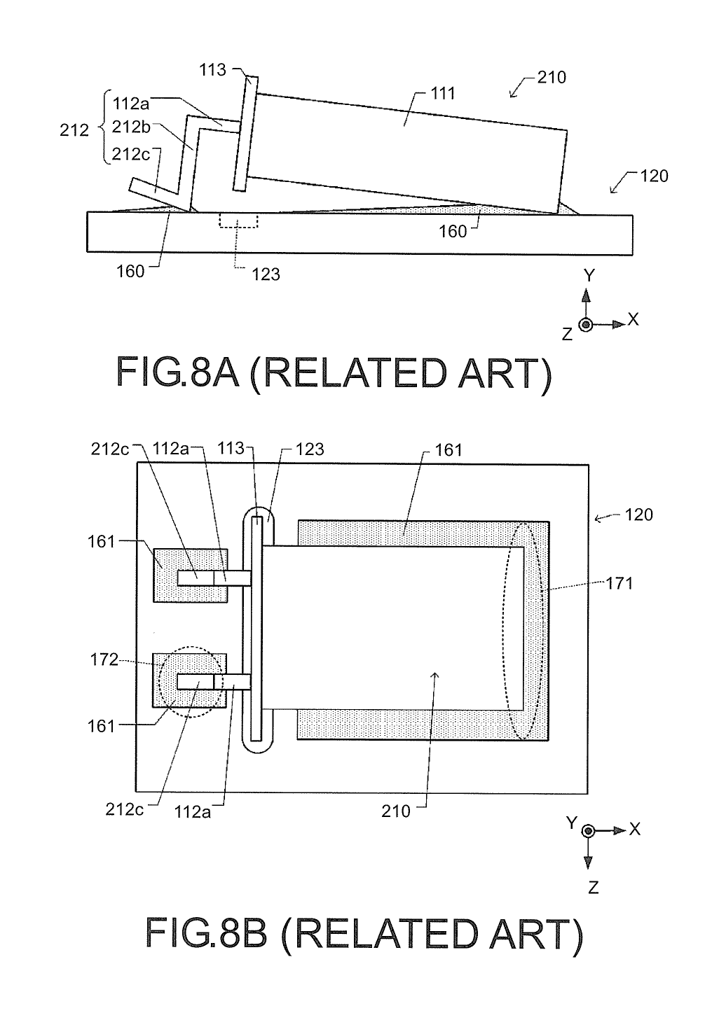

The piezoelectric resonator 110 is preferred to be configured as follows. The third part 112c of the lead terminal 112 extends in the X-axis direction. The third part 112c and the surface of the −Y-axis side of the metal case 111 are formed so as to be present on the same plane. This is because the piezoelectric resonator 110 is stably placed on the printed circuit board 120 and a contact failure is less likely to occur. However, due to such as a manufacturing error, the length of the second part 112b of the lead terminal 112 and the direction that the third part 112c extends may not meet these conditions. In such case, as illustrated in FIG. 8A and FIG. 8B, which will be described later, a connection failure is liable to occur between the lead terminal 112 and the printed circuit board 120. The following describes a method for mounting a piezoelectric resonator 210 on the printed circuit board 120 without contact failure even if the piezoelectric resonator 110 is formed as the piezoelectric resonator 210 with a manufacturing error.

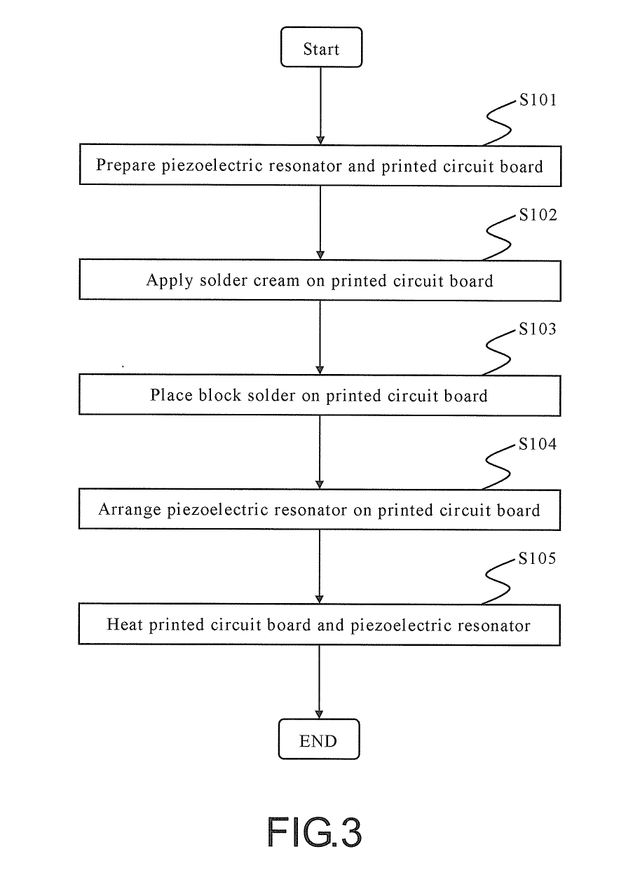

FIG. 3 is a flowchart illustrating a method for mounting the piezoelectric resonator 110 on the printed circuit board 120. The flowchart of FIG. 3 is also applicable to the case where the piezoelectric resonator 110 makes the piezoelectric resonator 210 with a manufacturing error. The following describes the method for mounting the piezoelectric resonator 210 on the printed circuit board 120 by referring to the flowchart of FIG. 3.

At Step S101 of FIG. 3, the piezoelectric resonator 110 and the printed circuit board 120 are prepared. In the following description, a case where the piezoelectric resonator 210, which is the piezoelectric resonator 110 with a manufacturing error, is used is described.

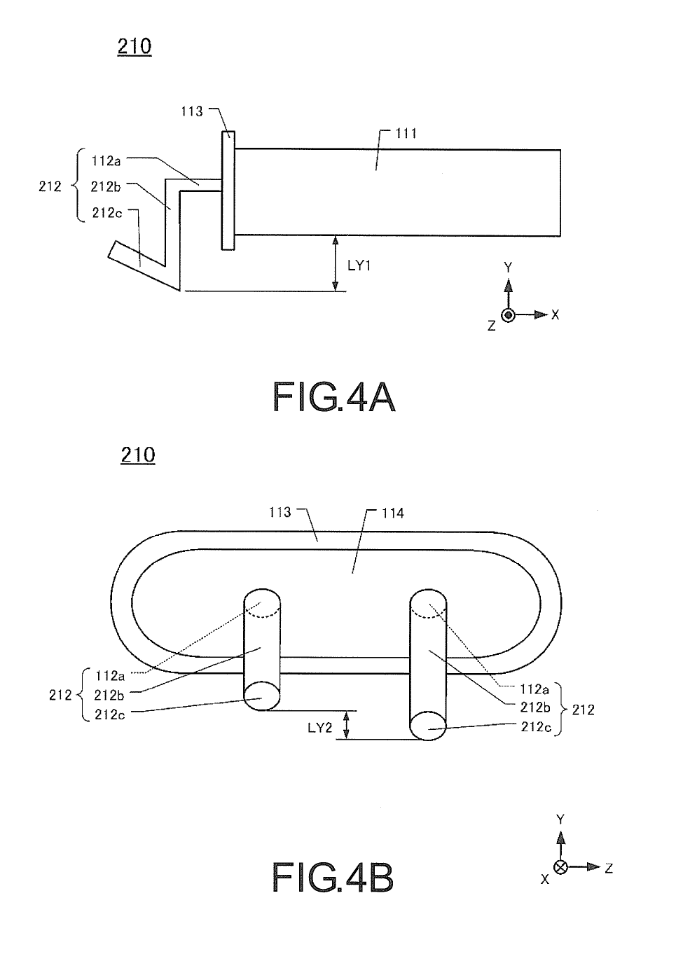

FIG. 4A is a side view of the piezoelectric resonator 210. A lead terminal 212 of the piezoelectric resonator 210 includes the first part 112a, a second part 212b, and a third part 212c. The first part 112a extends from the metal case 111 to the −X-axis direction. The second part 212b is bonded on the end of the −X-axis side of the first part 112a and extends in the −Y-axis direction. The third part 212c extends from the end of the −Y-axis side of the second part 212b to the −X-axis direction. The second part 212b of one or both of the lead terminals 212 is formed longer than a specified length. For example, in the ordinary piezoelectric resonator 110, the end of the −Y-axis side of the second part 112b is formed on the same plane as the surface of the −Y-axis side of the metal case 111. However, the end of the −Y-axis side of the second part 212b of the lead terminal 212, which is formed at the +Z-axis side of the piezoelectric resonator 210, is formed at the −Y-axis side with respect to the plane including the surface of the −Y-axis side of the metal case 111 by a length LY1. In the ordinary piezoelectric resonator 110, the third part 112c extends from the end of the −Y-axis side of the second part 112b in the −X-axis direction. However, the third part 212c of the piezoelectric resonator 210 extends to the −X-axis direction deviating toward the +Y-axis side.

FIG. 4B is a front view of the piezoelectric resonator 210. The end of the −Y-axis side of the second part 212b of the lead terminal 212 on the −Z-axis side of the piezoelectric resonator 210 is positioned at the +Y-axis side by a length LY2 with respect to the end of the −Y-axis side of the second part 212b of the lead terminal 212 on the +Z-axis side.

Returning to FIG. 3, at Step S102, the solder cream 161 is applied over the printed circuit board 120. Step S102 is an application process of applying the solder cream 161. The solder cream 161 is a paste-like material where solder and flux are mixed. The solder cream 161 is applied over the case region 121 and the lead regions 122 of the printed circuit board 120. The solder cream 161 is also applied over an oscillation device region (not illustrated) where an oscillation device of the printed circuit board 120 is formed.

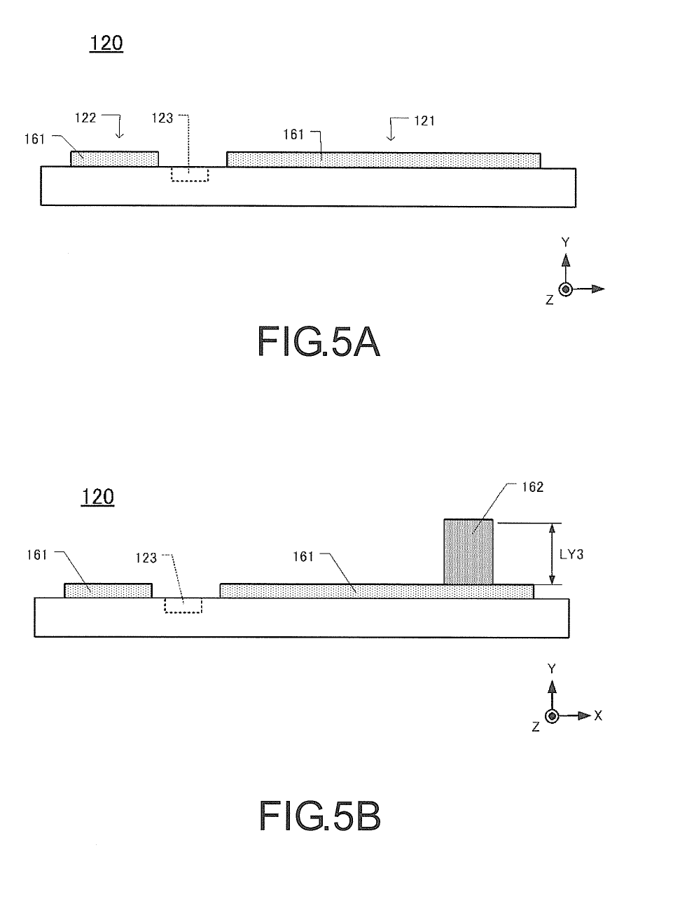

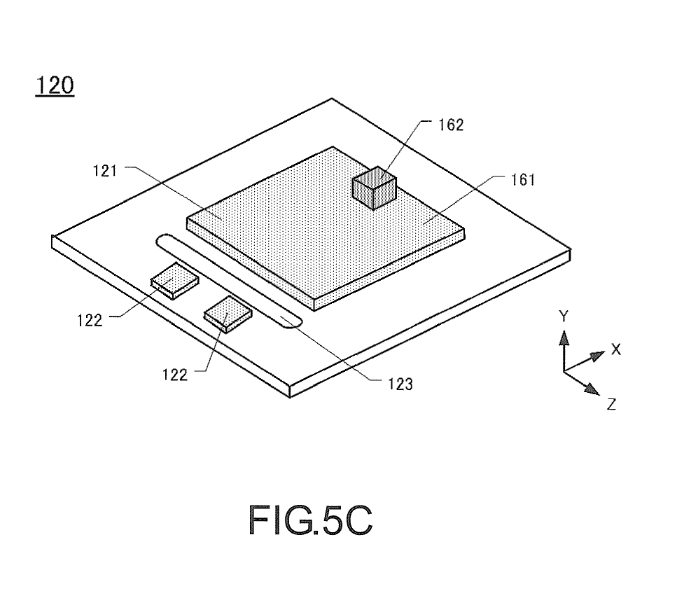

FIG. 5A is a side view of the printed circuit board 120 on which the solder cream 161 is applied. The solder cream 161 is applied over each of the case region 121 and the lead regions 122 of the printed circuit board 120 at a predetermined thickness.

At Step S103, the block solder 162 is placed on the printed circuit board 120. Step S103 is a placing process of placing the block solder 162. The block solder 162 has the same composition materials as the solder cream 161. However, adjusting the composition ratio of the composition material forms the block solder 162 with stronger viscosity than viscosity of the solder cream 161 or forms the block solder 162 in solid. Accordingly, the block solder 162 can be disposed on the printed circuit board 120 without its form being liable to break apart.

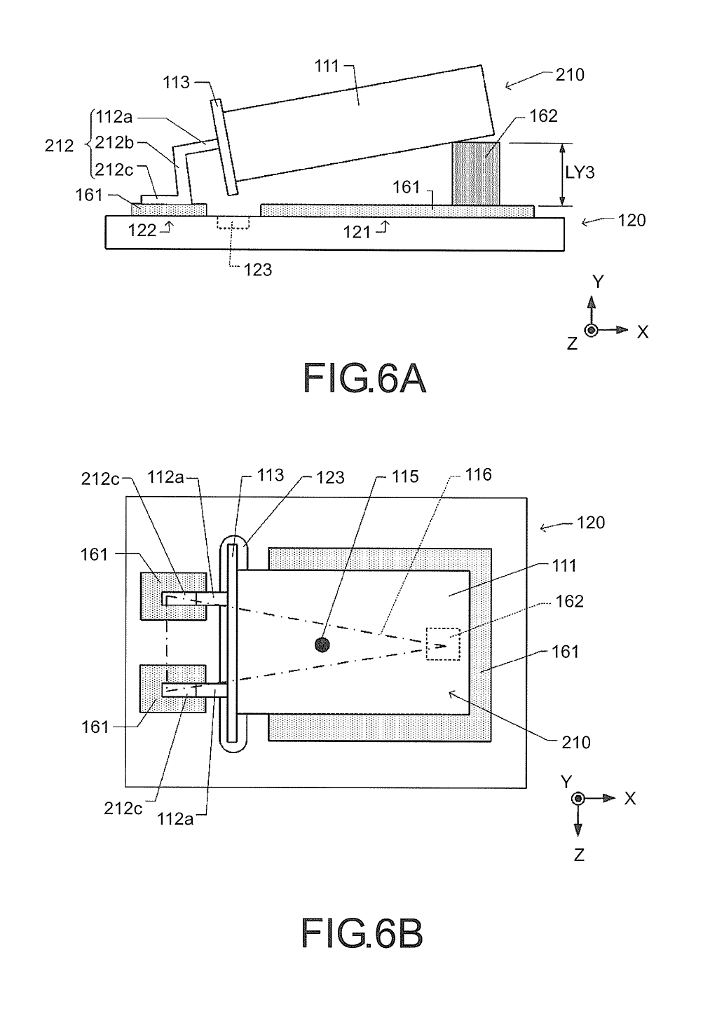

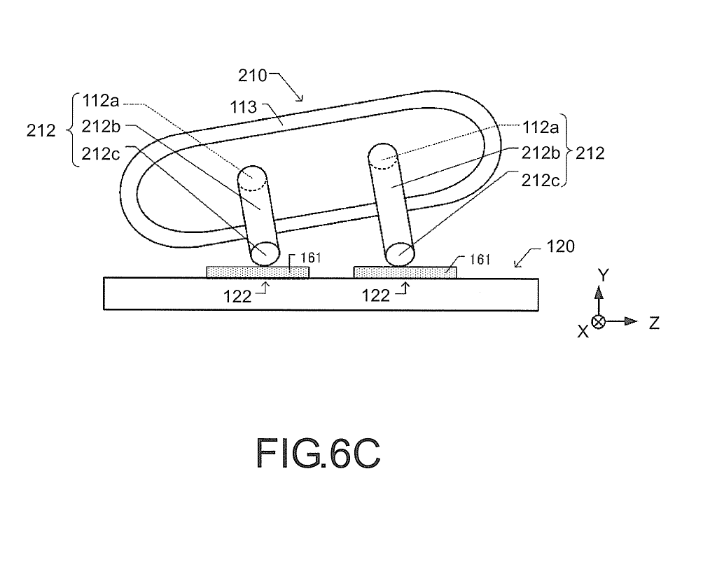

FIG. 5B is a side view of the printed circuit board 120 where the block solder 162 is placed. The block solder 162 is disposed at the case region 121 of the printed circuit board 120. As illustrated in FIG. 6A, which will be described later, the block solder 162 is disposed on the +X-axis side of the case region 121 so as to contact the +X-axis side of the metal case 111 of the piezoelectric resonator 210. A height LY3 of the block solder 162 is determined appropriately considering a manufacturing error or a similar error to be predicted such that a distal end on the −X-axis side of the third part 212c contacts the printed circuit board 120 at Step S104, which will be described later.

FIG. 5C is a perspective view of the printed circuit board 120 where the block solder 162 is placed. The block solder 162 can be formed to a shape similar to, for example, a cube as illustrated in FIG. 5C. The block solder 162 can be disposed at the center of the case region 121, for example, with respect to the Z-axis direction.

Returning to FIG. 3, at Step S104, the piezoelectric resonator 210 is arranged on the printed circuit board 120. Step S104 is an arrangement process of the piezoelectric resonator. At Step S104, the oscillation device is also arranged at the oscillation device region of the printed circuit board 120.

FIG. 6A is a side view of the printed circuit board 120 and the piezoelectric resonator 210. In the case where the piezoelectric resonator 210 is placed on the printed circuit board 120, as illustrated in FIG. 6A, the +X-axis side of the metal case 111 is lifted by the block solder 162. Therefore, the piezoelectric resonator 210 is installed such that the end of the −X-axis side of the third part 212c of the lead terminal 212 contacts the printed circuit board 120.

FIG. 6B is a plan view of the printed circuit board 120 and the piezoelectric resonator 210. When the piezoelectric resonator 210 is placed on the printed circuit board 120, the piezoelectric resonator 210 is placed on the printed circuit board 120 so as to contact the printed circuit board 120 at three points: a part contacting the block solder 162 at the +X-axis side of the metal case 111 and distal ends of the −X-axis side of the third parts 212c of the pair of lead terminals 212 via the solder cream 161 or the block solder 162. At this time, a barycentric position 115 of the piezoelectric resonator 210 is present inside of a triangle 116. The triangle 116 is formed by connecting respective contact points of the piezoelectric resonator 210 and the printed circuit board 120. Thus, the block solder 162 is disposed at the printed circuit board 120 such that the barycentric position 115 is formed in the triangle 116. Then, the piezoelectric resonator 210 is disposed at the printed circuit board 120. Accordingly, the piezoelectric resonator 210 can be disposed such that the distal ends of the −X-axis side of the third part 212c of the pair of lead terminals 212 contact the printed circuit board 120.

FIG. 6C is a front view of the printed circuit board 120 and the piezoelectric resonator 210. In the piezoelectric resonator 210 placed on the printed circuit board 120, lower ends of the pair of lead terminals 212 are not present in the same XZ plane. However, as illustrated in FIG. 6C, an inclination of the piezoelectric resonator 210 brings both lead terminals 212 in contact with the printed circuit board 120 via the solder cream 161. This inclination occurs when the metal case 111 is supported at a region nearly a point by the block solder 162 and the barycentric position 115 is formed in the triangle 116. Bringing both the lead terminals 212 in contact with the printed circuit board 120 electrically connects both the lead terminals 212 to the printed circuit board 120.

Returning to FIG. 3, at Step S105, the printed circuit board 120 and the piezoelectric resonator 210 are heated. Step S105 is a heating process. The printed circuit board 120 and the piezoelectric resonator 210 are heated in a reflow furnace (not illustrated). Thus, the printed circuit board 120 and the piezoelectric resonator 210 are bonded.

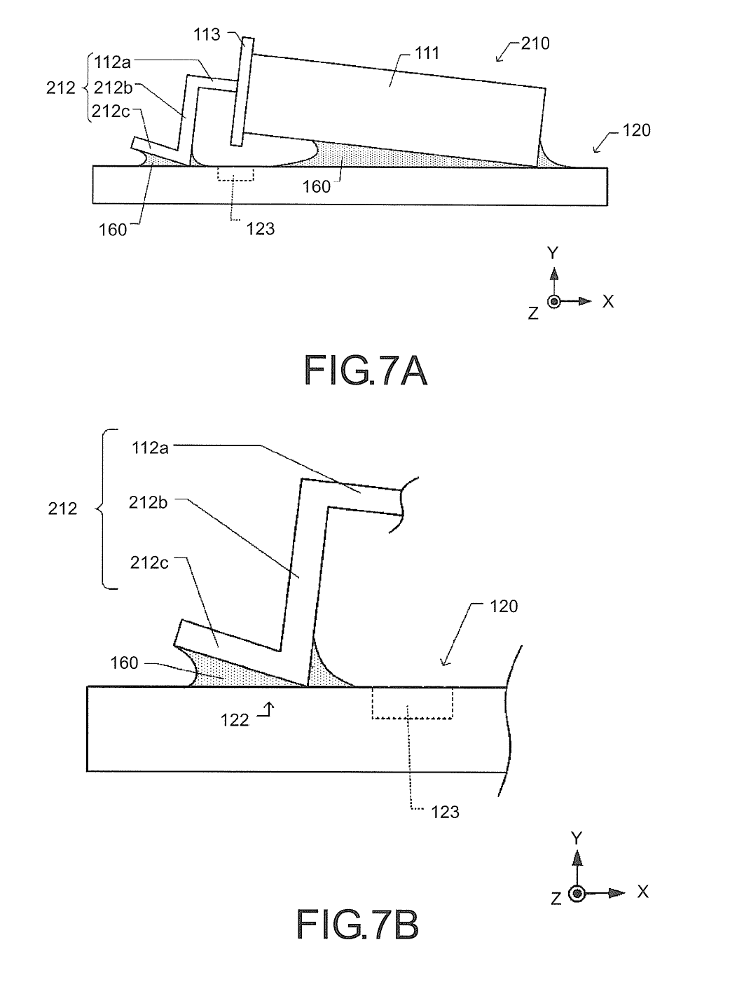

FIG. 7A is a side view of the printed circuit board 120 and the piezoelectric resonator 210 bonded to one another. Heating the printed circuit board 120 and the piezoelectric resonator 210 in the reflow furnace melts solder constituents of the solder cream 161 and the block solder 162. Further, the printed circuit board 120 and the piezoelectric resonator 210 are bonded to one another by cooling. In the piezoelectric resonator 210, melting the block solder 162 lowers the metal case 111 to the −Y-axis direction and then brings the metal case 111 in contact with the printed circuit board 120.

FIG. 7B is an enlarged figure of the lead terminal 212 bonded on the printed circuit board 120. In the piezoelectric resonator 210, melting the block solder 162 lowers the +X-axis side of the metal case 111 to the −Y-axis direction. In accordance with this, the distal end on the −X-axis side of the third part 212c of the lead terminal 212 is lifted, and the distal end separates from the printed circuit board 120. However, since the third part 212c of the lead terminal 212 contacts the printed circuit board 120 in a state in FIG. 6A, in a state in FIG. 7B where the printed circuit board 120 contacts the piezoelectric resonator 210, the solder 160 finally adheres to the entire third part 212c.

FIG. 8A is a side view of the printed circuit board 120 and the piezoelectric resonator 210 bonded to one another using a conventional method. In the conventional method, Step S103 in the flowchart of FIG. 3 does not exist. Therefore, in a state where the piezoelectric resonator 210 is placed on the printed circuit board 120, the distal end of the −X-axis side of the third part 212c of the lead terminal 212 does not contact the printed circuit board 120. Since the piezoelectric resonator 210 is secured to the printed circuit board 120 in the state, as illustrated in FIG. 8A, the distal end of the −X-axis side of the third part 212c does not contact the solder 160. Therefore, the lead terminals 212 and the printed circuit board 120 are bonded at point contact. The lead terminal 212 is prone to be peeled off from the printed circuit board 120, possibly being electrically insulated.

FIG. 8B is a plan view of the printed circuit board 120 and the piezoelectric resonator 210 bonded to one another using a conventional method. As illustrated in FIG. 4B, the end of the −Y-axis side of the lead terminal 212 at the −Z-axis side of the piezoelectric resonator 210 is positioned on the +Y-axis side by the length LY2 with respect to the end of the −Y-axis side of the lead terminal 212 on the +Z-axis side. The conventional method does not dispose the block solder 162. Accordingly, in a state where the piezoelectric resonator 210 is placed on the printed circuit board 120, the entire side at the +X-axis side of the metal case 111 indicated by a dotted line 171 in FIG. 8B and the lead terminal 212 at the +Z-axis side indicated by a dotted line 172 in FIG. 8B contact the printed circuit board 120, thus the piezoelectric resonator 210 is stably positioned. Accordingly, the lead terminal 212 at the −Z-axis side does not contact the printed circuit board 120, possibility being electrically insulated.

Contrary to the problem of the conventional method as illustrated in FIG. 8A, with the mounting method illustrated in the flowchart of FIG. 3, as illustrated in FIG. 7B, forming the solder 160 at the entire third part 212c makes the lead terminal 212 difficult to be peeled off from the printed circuit board 120 and prevents electrical insulation. Contrary to the problem of the conventional method as illustrated in FIG. 8B, with the mounting method illustrated in the flowchart of FIG. 3, as illustrated in FIG. 6B and FIG. 6C, placing the block solder 162 on the printed circuit board 120 such that both of the lead terminals 212 on the +Z-axis side and the −Z-axis side contact the printed circuit board 120. This prevents the problem that the one lead terminal 212 is not bonded on the printed circuit board 120. Accordingly, the piezoelectric device 100 that includes the mounting method shown in the flowchart of FIG. 3 in the method for fabricating the piezoelectric device, the pair of lead terminals 212 and the printed circuit board 120 are reliably bonded.

Representative embodiments of this disclosure are described in detail above; however, as will be evident to those skilled in the relevant art, this disclosure may be changed or modified in various ways within its technical scope.

For example, the solder cream 161 is formed at the case region 121. Only the block solder 162 may be formed without applying the solder cream 161, and the metal case 111 and the printed circuit board 120 may be bonded with the block solder 162 only. The block solder 162 is formed to a shape similar to a cube in FIG. 5B. However, the block solder 162 may be formed in a cone, and the metal case 111 may be supported by the block solder 162 in a nearly point state. Furthermore, the block solder 162 may be formed by dropping solder cream with high viscosity to the extent that the form of the block solder 162 is not liable to break apart with a syringe or a similar tool.

In the printed circuit board 120, the hollow 123 is formed at a part where the flange 113 contacts. Alternatively, instead of forming the hollow 123 at the printed circuit board 120, a metal plate (not illustrated) may be inserted between the metal case 111 and the printed circuit board 120, and a height of the piezoelectric resonator may be adjusted such that the flange 113 does not contact the printed circuit board 120. At this time, the printed circuit board 120, the metal plate, and the metal case 111 are bonded to one another with solder. For use of the piezoelectric resonator with the small flange 113 (height is low) or without the flange 113, the hollow 123 may not be formed.

Furthermore, in the above-described embodiment, the piezoelectric device 100 is described as an oven-controlled piezoelectric oscillator (OCXO). However, the described method for fabricating the piezoelectric device may be applicable to a fabrication of another piezoelectric device where a metal case of a piezoelectric resonator is bonded on a printed circuit board with solder.

In the first aspect of the disclosure, the method for fabricating a piezoelectric device according to a second aspect is configured as follows. The applying process applies the solder cream on an oscillation device region corresponding to an oscillation device that oscillates the piezoelectric piece. The arranging process disposes the oscillation device.

In the first aspect and the second aspect of the disclosure, the method for fabricating a piezoelectric device according to a third aspect is configured as follows. The placing process places the block solder such that a barycentric position of a longitudinal direction of the piezoelectric resonator is located between the third part and the block solder, when arranging the piezoelectric resonator.

In the first aspect to the third aspect of the disclosure, the method for fabricating a piezoelectric device according to a fourth aspect is configured as follows. The block solder is a cone. In the arranging process, the block solder and the metal case are contacted at a point.

The disclosure provides a method for fabricating a piezoelectric device that prevents a contact failure between a pair of lead terminals of a piezoelectric resonator and a substrate.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A method for fabricating a piezoelectric device, wherein
the piezoelectric device includes a piezoelectric resonator to be mounted on a solder applied over a surface of a substrate, the piezoelectric resonator including a metal case and at least a pair of lead terminals extracted from the metal case, the metal case housing a piezoelectric piece, and
the lead terminal includes a first part, a second part, and a third part, the first part being extracted parallel to a longitudinal direction of the metal case, the second part being then perpendicularly bent to the longitudinal direction, the third part being again bent to the longitudinal direction, wherein
the method for fabricating a piezoelectric device comprises:
an applying process, for applying a solder cream at a case region and a lead region of a surface of the substrate, the case region is corresponding to the metal case, the lead region is corresponding to the third part;
a placing process, for placing a block solder at the case region, and the block solder has a smaller area than an area of the case region;
an arranging process, for arranging the metal case of the piezoelectric resonator to the case region, and arranging the third part to the lead region; and
a heating process, for heating the substrate and the piezoelectric resonator in a reflow furnace.

2. The method for fabricating a piezoelectric device according to claim 1, wherein
the applying process applies the solder cream on an oscillation device region corresponding to an oscillation device that oscillates the piezoelectric piece, and
the arranging process disposes the oscillation device.

3. The method for fabricating a piezoelectric device according to claim 1, wherein
the placing process places the block solder such that a barycentric position of a longitudinal direction of the piezoelectric resonator is located between the third part and the block solder, when arranging the piezoelectric resonator.

4. The method for fabricating a piezoelectric device according to claim 2, wherein
the placing process places the block solder such that a barycentric position of a longitudinal direction of the piezoelectric resonator is located between the third part and the block solder, when arranging the piezoelectric resonator.

5. The method for fabricating a piezoelectric device according to claim 1, wherein
the block solder is a cone, and
the block solder and the metal case are contacted at a point in the arranging process.

6. The method for fabricating a piezoelectric device according to claim 2, wherein
the block solder is a cone, and
the block solder and the metal case are contacted at a point in the arranging process.

7. The method for fabricating a piezoelectric device according to claim 3, wherein
the block solder is a cone, and
the block solder and the metal case are contacted at a point in the arranging process.

8. The method for fabricating a piezoelectric device according to claim 4, wherein
the block solder is a cone, and
the block solder and the metal case are contacted at a point in the arranging process.
